(19) United States
(12) Patent Application Publication
(10) Pub. No.: US 2020/0103991 A1
(43) Pub. Date: Apr. 2, 2020

(54) DISPLAY PANEL, DISPLAY MODULE AND ELECTRONIC DEVICE

(71) Applicant: Wuhan China Star Optoelectronics Technology Co., Ltd., Wuhan (CN)

(72) Inventors: Xiaohui NIE, Wuhan (CN); Jiawei ZHANG, Wuhan (CN)

(73) Assignee: Wuhan China Star Optoelectronics Technology Co., Ltd., Wuhan (CN)

(21) Appl. No.: 16/309,112

(22) PCT Filed: Nov. 15, 2018
(86) PCT No.: PCT/CN2018/115529

§ 371 Date: Dec. 12, 2018

(30) Foreign Application Priority Data
Sep. 29, 2018 (CN) 201811149656.4

(51) Int. Cl. G06F 3/044; H01L 27/32; G02F 1/1362; G02F 1/1333; G06F 3/041

(52) U.S. Cl. CPC G06F 3/044; H01L 27/3288; G06F 3/0412; G02F 1/13338; G02F 1/136286

(57) ABSTRACT

A display panel, a display module and an electronic device are provided. The display panel comprises a displaying region, a non-displaying region located on a periphery of the displaying region, wires comprising a first portion located in the displaying region and transmission portions located in the non-displaying region. Line shapes of some of the transmission portions are wave-like line shapes.

### FIELD OF INVENTION

The present invention relates to fields of displays, especially to a display panel, a display module and an electronic device.

### BACKGROUND OF INVENTION

In the conventional embedded touch technology, touch sensors are classified into self-capacitance sensors and mutual capacitance sensors. The self-capacitance touch screen (single layer multi-touch) divides the screen into M×N regions, and each region is an individual transparent conductive electrode block. Each transparent conductive electrode block is connected to an integrated circuit (IC) through signal wires on a same layer. The signal wires extend to the bonding area through fan-out wires in the non-displaying region, and are connected to a driver chip.

In an actual manufacturing process of a display panel, because the signal wires are formed on a non-metal film layer by a physical vapor deposition process, therefore a greater stress exists between the signal wires and the non-metal film layer such that the fan-out wires between the displaying region and the bonding area are easily broken due to fall or other external force during application of the display panel and cause failure of touch functions of the display panel, which decreases stability of the product.

### SUMMARY OF INVENTION

The present invention provides a display panel, a display module and an electronic device to solve a technical issue that signal wires in a conventional display panel non-displaying region are easily broken.

To solve the above technical issue, the present invention provides technical solutions as follows.

The present invention provides a display panel, comprising:

displaying region;

a non-displaying region located on a periphery of the displaying region; and

a plurality of wires comprising a first portion located in the displaying region and transmission portions located in the non-displaying region;

wherein line shapes of some of the transmission portions are wave-like line shapes.

In the display panel of the present invention, the non-displaying region comprises a first area and a second area, the first area is located close to the displaying region, the second area is located far away from the displaying region, and the first area is located between the displaying region and the second area; and

wherein the transmission portions comprise first fan-out wires of located in the first area and second fan-out wires located in the second area, line shapes of the second fan-out wires are wave-like line shapes.

In the display panel of the present invention, the shapes of the second fan-out wires are curvy wave shapes or zigzag wave shapes.

In the display panel of the present invention, the second area comprises a substrate, and the second fan-out wires located on the substrate; and

wherein a buffer layer is disposed between the substrate and the second fan-out wires.

In the display panel of the present invention, the second area further comprises recesses located in the buffer layer; and

wherein a number of the recesses is equal to a number of the second fan-out wires, and the second fan-out wires are disposed in the recesses respectively.

In the display panel of the present invention, along a direction of a top view of display panel, line shapes of the recesses are curvy wave line shapes or zigzag wave line shapes.

In the display panel of the present invention, the second fan-out wires comprise metal wires arranged abreast and insulated from one another, and each of the metal wires comprises at least one row/column through holes; and

wherein each of the at least one row/column of the through holes comprises a plurality of the through holes.

In the display panel of the present invention, shapes of the through holes are circular shapes, elliptical shapes, or mixtures of the circular shapes and the elliptical shapes.

The present invention provides a display module, comprising a display panel, a touch layer located on the display panel, a polarization layer and a covering layer, wherein the display panel comprises:

a displaying region;

a non-displaying region located on a periphery of the displaying region; and

a plurality of wires comprising a first portion located in the displaying region and transmission portions located in the non-displaying region;

wherein line shapes of some of the transmission portions are wave-like line shapes.

In the display module of the present invention, the non-displaying region comprises a first area and a second area, the first area is located close to the displaying region, the second area is located far away from the displaying region, and the first area is located between the displaying region and the second area; and

wherein the transmission portions comprise first fan-out wires of located in the first area and second fan-out wires located in the second area, line shapes of the second fan-out wires are wave-like line shapes.

In the display module of the present invention, the shapes of the second fan-out wires are curvy wave shapes or zigzag wave shapes.

In the display module of the present invention, the second area comprises a substrate, and the second fan-out wires located on the substrate; and

wherein a buffer layer is disposed between the substrate and the second fan-out wires.

In the display module of the present invention, the second area further comprises recesses located in the buffer layer;

wherein a number of the recesses is equal to a number of the second fan-out wires, and the second fan-out wires are disposed in the recesses respectively;

wherein along a direction of a top view of display panel, line shapes of the recesses are curvy wave line shapes or zigzag wave line shapes.

In the display module of the present invention, the second fan-out wires comprise metal wires arranged abreast and insulated from one another, and each of the metal wires comprises at least one row/column through holes; and

wherein each of the at least one row/column of the through holes comprises a plurality of the through holes.

The present invention also provides an electronic device, comprising a display module, wherein the display module comprises a display panel and a touch layer located on the display panel, a polarization layer and a covering layer, and the display panel comprises:

a displaying region;

a non-displaying region located on a periphery of the displaying region; and

a plurality of wires comprising a first portion located in the displaying region and transmission portions located in the non-displaying region;

wherein line shapes of some of the transmission portions are wave-like line shapes.

In the electronic device of the present invention, the non-displaying region a first area and a second area, the first area is located close to the displaying region, the second area is located far away from the displaying region, and the first area is located between the displaying region and the second area; and

wherein the transmission portions comprise first fan-out wires of located in the first area and second fan-out wires located in the second area, line shapes of the second fan-out wires are wave-like line shapes.

In the electronic device of the present invention, the shapes of the second fan-out wires are curvy wave shapes or zigzag wave shapes.

In the electronic device of the present invention, the second area comprises a substrate, and the second fan-out wires located on the substrate; and

wherein a buffer layer is disposed between the substrate and the second fan-out wires.

In the electronic device of the present invention, the second area further comprises recesses located in the buffer layer;

wherein a number of the recesses is equal to a number of the second fan-out wires, and the second fan-out wires are disposed in the recesses respectively; and

wherein along a direction of a top view of display panel, line shapes of the recesses are curvy wave line shapes or zigzag wave line shapes.

In the electronic device of the present invention, the second fan-out wires comprise metal wires arranged abreast and insulated from one another, and each of the metal wires comprises at least one row/column through holes; and

wherein each of the at least one row/column of the through holes comprises a plurality of the through holes.

Advantages: The present invention, by setting the metal wires between the displaying region and the bonding area with the wave-like line shape and disposing a buffer layer between the metal wires and the insulating layer under the metal wires, excellently mitigates stress concentration and improves quality of the production.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

FIG. 1 is a schematic plan view of a display panel of the present invention;

FIG. 2 is a cross-sectional view of the display panel along line A-A in FIG. 1;

FIG. 3 is a schematic structure view of the second fan-out wires in the display panel of the present invention;

FIG. 4 is a first cross-sectional view of the display panel along line B-B in FIG. 1; and

FIG. 5 is a second cross-sectional view of the display panel along line B-B in FIG. 1.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference characters.

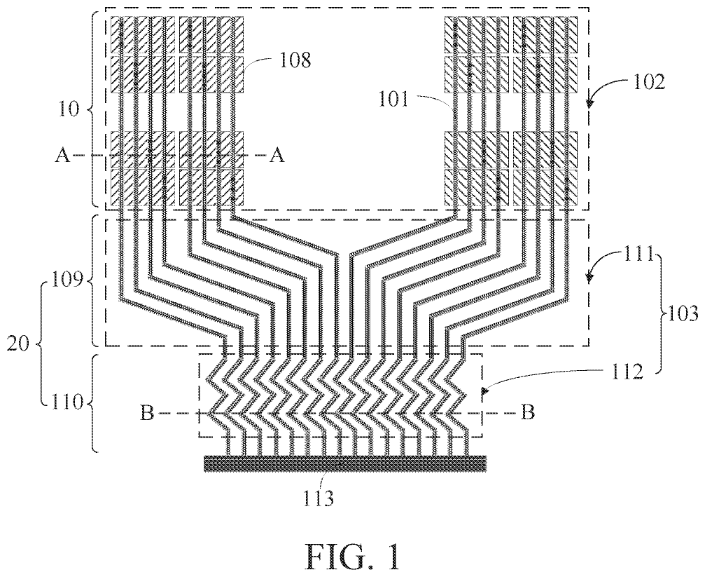

With reference to FIG. 1, FIG. 1 is a schematic plan view of a display panel of the present invention.

The display panel comprises a displaying region 10 and a non-displaying region 20 located in the displaying region 10 periphery. The displaying region 10 is configured for displaying images.

The display panel further comprises wires 101, and the wires 101 comprises a first portion 102 located in the displaying region 10, and transmission portions 103 located in the non-displaying region 20.

In an embodiment, line shapes of some of the transmission portions 103 are wave-like line shapes.

In the present embodiment, the wires 101 are touch wires of the display panel.

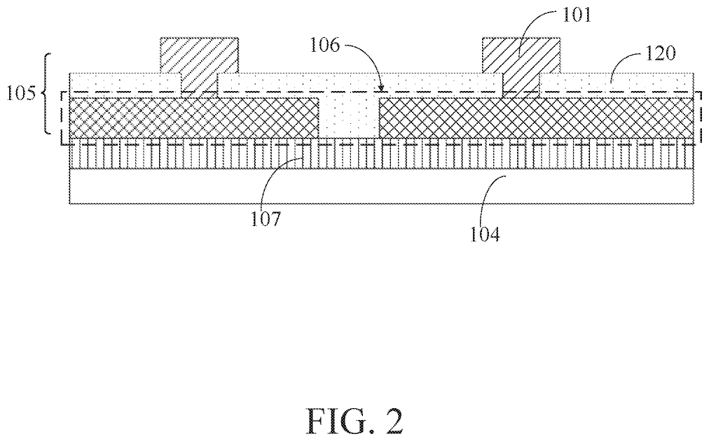

With reference to FIG. 2, FIG. 2 is a cross-sectional view of the display panel along line A-A in FIG. 1.

The displaying region 10 comprises a substrate 104 and a touch layer 105 located on the substrate 104. The touch layer 105 comprises a first insulating layer 107 located on the substrate 104, a first common electrode layer 106 located on the first insulating layer 107, a second insulating layer 120 located on the first common electrode layer 106, and the first portion 102 located on the second insulating layer 120. The first portion 102 comprises a plurality of the touch wires.

The first common electrode layer 106 comprises at least two sets of first common electrode plates 108 distributed in arrays. A number of the touch wires corresponds to a number of the first common electrode plates 108. The touch wires connected to the first common electrode plates 108 through corresponding via holes.

With reference to FIG. 1, the non-displaying region 20 comprises a first area 109 and a second area 110. The first area 109 is locate close to the displaying region 10, and the second area 110 is located far away from the displaying region 10. The first area 109 is located between the displaying region 10 and the second area 110.

The transmission portions 103 comprises first fan-out wires 111 located in the first area 109, and second fan-out wires 112 located in the second area 110. Line shapes of the second fan-out wires 112 are wave-like line shapes.

The first portion 102 in the touch wires extends from the displaying region 10 to the non-displaying region 20, through the first fan-out wires 111 in the first area 109, and the second fan-out wires 112 in the second area 110 is connected to a driver chip 113.

In an embodiment, the line shapes of the second fan-out wires 112 are zigzag wave shapes.

Folding a conventional straight line section into a folding line obtains better toughness. When the folding line is affected by an external force and deforms, anti-breaking ability thereof is stronger.

Under a same interval, when straight section is converted to a folding line section, a length of the folding line section becomes longer. When affected by a same external force, the folding line section has a greater force bearing area, a pressure exerted borne by the folding line section becomes less, and the anti-breaking ability thereof is stronger.

The display panel also comprises through holes located in the second fan-out wires 112.

The second fan-out wires 112 comprise a plurality of metal wires arranged abreast and insulated from one another. The metal wires can be the touch wires located in the second area 110.

In an embodiment, each of the metal wires comprises at least one row/column the through holes, and each of the at least one row/column the through holes comprises a plurality of the through holes.

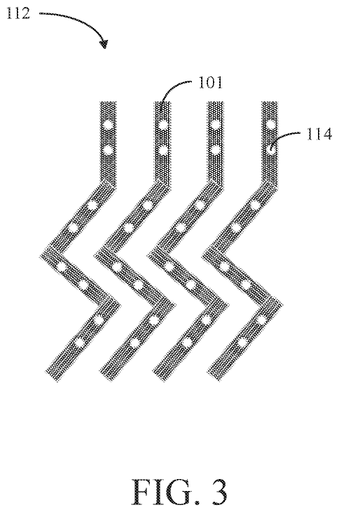

With reference to FIG. 3, FIG. 3 is a schematic structure view of the second fan-out wires in the display panel of the present invention.

In an embodiment, each of the folding wires 101 comprises a row of the through holes 114. The through holes are distributed evenly in the metal wires. Each folding metal wires can comprise two rows of the through holes 114 that are distributed evenly in the metal wires.

Along a direction of a top view of the display panel, shapes of the through holes 114 in the metal wires comprise but are not limited to circular shapes, elliptical shapes, or mixtures of the circular shapes and the elliptical shapes.

Sizes and a number of the through holes 114 are set depending on actual conditions, and the present invention will not set limitations thereto.

In an embodiment, the line shapes of the second fan-out wires 112 can be curvy wavy line shapes.

In an embodiment, the second fan-out wires 112 can also comprise through holes 114, and details will be no be repeated herein.

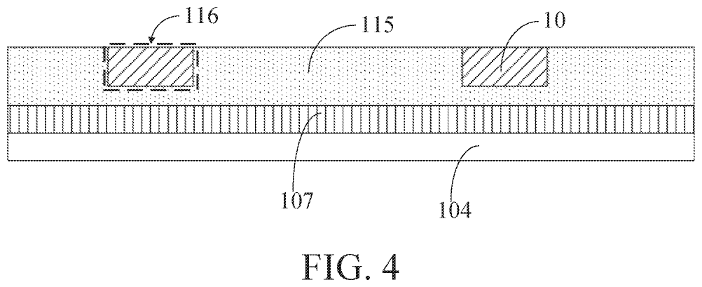

With reference to FIG. 4, FIG. 4 is a first cross-sectional view of the display panel along line B-B in FIG. 1.

The present embodiment is similar to the first embodiment, and difference thereof is as follows.

The display panel further comprises a buffer layer 115 between the substrate 104 located in the second area 110 and the second fan-out wires 112.

In an embodiment, recesses 116 are defined in the buffer layer 115. The recesses 116 are defined by an etching process, i.e., etching shapes of the recesses 116 are the line shapes of the second fan-out wires 112.

A number of the recesses 116 is equal to a number of the second fan-out wires 112, and the second fan-out wires 112 are disposed in the recesses 116 respectively.

In an embodiment, the buffer layer 115 can be made of a flexible organic material.

When affected by an external force, flexibility of the buffer layer 115 cushions the stress between the second fan-out wires 112 and the non-metal film layer, which improves stability of the product.

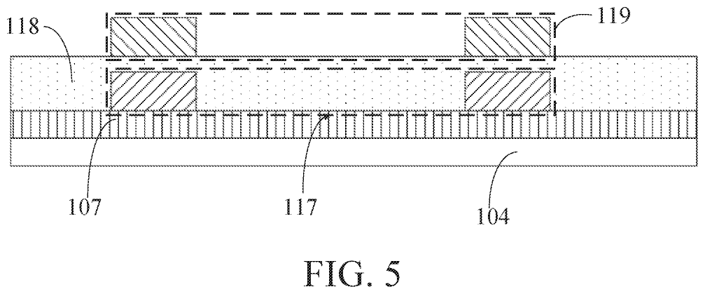

With reference to FIG. 5, FIG. 5 is a second cross-sectional view of the display panel along line B-B in FIG. 1.

The present embodiment is similar to first embodiment and the second embodiment, and difference thereof is as follows.

The second area 110 comprises the substrate 104, the first insulating layer 107 located on the substrate 104, a first touch wire layer 117 located on the first insulating layer 107, a third insulating layer 118 located on the first touch wire layer 117, and a second touch wire layer 119 located on the third insulating layer.

The second fan-out wires in the present invention employ two layers of the metal wires to perform signal transmission. When affected by an external force and one layer of the touch wires is broken, another layer of the touch wires still works well, which reduces risks of poor touch functions of the display panel. Furthermore, disposing double layers of the metal wires lowers impedance of the signal wires, increases speed of the signal transmission, and enhances touch sensitivity.

According to another aspect, the present invention also provides a display module, the display module [symbol] the [symbol] display panel.

According to still another aspect, the present invention also provides an electronic device, the electronic device comprises the display module. The electronic device comprises but is not limited to mobile phones, tablets, computer monitors, game consoles, televisions, display screens, wearable devices and other living appliances or household appliances with display functions.

The working principles of the display module and the electronic device are similar to that of the display panel. The working principle of the display module and the working principle of the electronic device can refer to the working principle of the display panel, and will not be described here.

The present invention provides a display panel, a display module and an electronic device, the display panel comprises: a displaying region; a non-displaying region located on a periphery of the displaying region; a plurality of wires, comprising a first portion located in the displaying region and transmission portions located in the non-displaying region. Line shapes of some of the transmission portions are wave-like shapes. The present invention, by setting the metal wires between the displaying region and the bonding area with the wave-like line shape and disposing a buffer layer between the metal wires and the insulating layer under the metal wires, excellently mitigates stress concentration and improves quality of the production.

Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

What is claimed is:

1. A display panel, comprising:
a displaying region;
a non-displaying region located on a periphery of the displaying region; and
a plurality of wires comprising a first portion located in the displaying region and transmission portions located in the non-displaying region;
wherein line shapes of some of the transmission portions are wave-like line shapes.

2. The display panel as claimed in claim 1, wherein the non-displaying region comprises a first area and a second area, the first area is located close to the displaying region, the second area is located far away from the displaying region, and the first area is located between the displaying region and the second area; and
wherein the transmission portions comprise first fan-out wires of located in the first area and second fan-out wires located in the second area, line shapes of the second fan-out wires are wave-like line shapes.

3. The display panel as claimed in claim 2, wherein the shapes of the second fan-out wires are curvy wave shapes or zigzag wave shapes.

4. The display panel as claimed in claim 2, wherein the second area comprises a substrate, and the second fan-out wires located on the substrate; and
wherein a buffer layer is disposed between the substrate and the second fan-out wires.

5. The display panel as claimed in claim 4, wherein the second area further comprises recesses located in the buffer layer; and
wherein a number of the recesses is equal to a number of the second fan-out wires, and the second fan-out wires are disposed in the recesses respectively.

6. The display panel as claimed in claim 5, wherein along a direction of a top view of display panel, line shapes of the recesses are curvy wave line shapes or zigzag wave line shapes.

7. The display panel as claimed in claim 2, wherein the second fan-out wires comprise metal wires arranged abreast and insulated from one another, and each of the metal wires comprises at least one row/column through holes; and
wherein each of the at least one row/column of the through holes comprises a plurality of the through holes.

8. The display panel as claimed in claim 7, wherein shapes of the through holes are circular shapes, elliptical shapes, or mixtures of the circular shapes and the elliptical shapes.

9. A display module, comprising a display panel, a touch layer located on the display panel, a polarization layer and a covering layer, wherein the display panel comprises:
a displaying region;
a non-displaying region located on a periphery of the displaying region; and
a plurality of wires comprising a first portion located in the displaying region and transmission portions located in the non-displaying region;
wherein line shapes of some of the transmission portions are wave-like line shapes.

10. The display module as claimed in claim 9, wherein the non-displaying region comprises a first area and a second area, the first area is located close to the displaying region, the second area is located far away from the displaying region, and the first area is located between the displaying region and the second area; and
wherein the transmission portions comprise first fan-out wires of located in the first area and second fan-out wires located in the second area, line shapes of the second fan-out wires are wave-like line shapes.

11. The display module as claimed in claim 10, the shapes of the second fan-out wires are curvy wave shapes or zigzag wave shapes.

12. The display module as claimed in claim 10, wherein the second area comprises a substrate, and the second fan-out wires located on the substrate; and
wherein a buffer layer is disposed between the substrate and the second fan-out wires.

13. The display module as claimed in claim 12, wherein the second area further comprises recesses located in the buffer layer;
wherein a number of the recesses is equal to a number of the second fan-out wires, and the second fan-out wires are disposed in the recesses respectively;
wherein along a direction of a top view of display panel, line shapes of the recesses are curvy wave line shapes or zigzag wave line shapes.

14. The display module as claimed in claim 10, wherein the second fan-out wires comprise metal wires arranged abreast and insulated from one another, and each of the metal wires comprises at least one row/column through holes; and
wherein each of the at least one row/column of the through holes comprises a plurality of the through holes.

15. An electronic device, comprising a display module, wherein the display module comprises a display panel and a touch layer located on the display panel, a polarization layer and a covering layer, and the display panel comprises:
a displaying region;
a non-displaying region located on a periphery of the displaying region; and
a plurality of wires comprising a first portion located in the displaying region and transmission portions located in the non-displaying region;
wherein line shapes of some of the transmission portions are wave-like line shapes.

16. The electronic device as claimed in claim 15, wherein the non-displaying region a first area and a second area, the first area is located close to the displaying region, the second area is located far away from the displaying region, and the first area is located between the displaying region and the second area; and
wherein the transmission portions comprise first fan-out wires of located in the first area and second fan-out wires located in the second area, line shapes of the second fan-out wires are wave-like line shapes.

17. The electronic device as claimed in claim 16, wherein the shapes of the second fan-out wires are curvy wave shapes or zigzag wave shapes.

18. The electronic device as claimed in claim 16, wherein the second area comprises a substrate, and the second fan-out wires located on the substrate; and
wherein a buffer layer is disposed between the substrate and the second fan-out wires.

19. The electronic device as claimed in claim 18, wherein the second area further comprises recesses located in the buffer layer;
wherein a number of the recesses is equal to a number of the second fan-out wires, and the second fan-out wires are disposed in the recesses respectively; and
wherein along a direction of a top view of display panel, line shapes of the recesses are curvy wave line shapes or zigzag wave line shapes.

20. The electronic device as claimed in claim 16, wherein the second fan-out wires comprise metal wires arranged abreast and insulated from one another, and each of the metal wires comprises at least one row/column through holes; and
wherein each of the at least one row/column of the through holes comprises a plurality of the through holes.
